(19) United States
(12) Patent Application Publication
(10) Pub. No.: US 2025/0063735 A1
(43) Pub. Date: Feb. 20, 2025

(54) SEMICONDUCTOR DEVICE AND MANUFACTURING METHOD OF THE SAME

(71) Applicant: Kioxia Corporation, Tokyo (JP)

(72) Inventors: Masaki NOGUCHI, Yokkaichi Mie (JP); Tatsunori ISOGAI, Yokkaichi Mie (JP); Fumiki AISO, Nagoya Aichi (JP)

(21) Appl. No.: 18/797,425

(22) Filed: Aug. 7, 2024

(30) Foreign Application Priority Data
Aug. 15, 2023 (JP) 2023-132347

(51) Int. Cl. H10B 43/35; H10B 43/10; H10B 43/27

(52) U.S. Cl. CPC H10B 43/35; H10B 43/10; H10B 43/27

(57) ABSTRACT

A semiconductor device includes a stacked body of electrode layers and insulating layers that are alternately stacked in a first direction. A semiconductor layer is disposed in the stacked body along the first direction. A first insulating film extends in the first direction between the stacked body and the semiconductor layer. A first charge storage film extends in the first direction and is disposed between the stacked body and the first insulating film. A second insulating film is disposed between the insulating layers and the first charge storage film. A second charge storage film extends in the first direction and is disposed between the electrode layers and the first charge storage film and in contact with the second insulating film in the first direction. A third insulating film is disposed between the electrode layers and the second charge storage film.

### CROSS-REFERENCE TO RELATED APPLICATION(S)

This application is based upon and claims the benefit of priority from Japanese Patent Application No. 2023-132347, filed Aug. 15, 2023, the entire contents of which are incorporated herein by reference.

### FIELD

Embodiments described herein relate generally to a semiconductor device and a manufacturing method of the same.

### BACKGROUND

A NAND flash memory in which memory cells are three-dimensionally arranged is known as one type of a semiconductor device. In the NAND flash memory, a stacked body in which a plurality of electrode layers and insulating layers are alternately stacked is provided with a memory hole passing through the stacked body. By providing a charge storage layer and a semiconductor layer in the memory hole, a memory string in which a plurality of memory cells are connected in series is formed. Data is stored in the memory cell by controlling amounts of charges held in the charge storage layer.

### BRIEF DESCRIPTION OF THE DRAWINGS

FIGS. 1A and 1B are schematic sectional views of a memory cell of a semiconductor device of a first embodiment.

FIGS. 2-11 are sectional views illustrating a process for manufacturing the semiconductor device according to the first embodiment.

FIGS. 12-13 are sectional views illustrating a process for manufacturing a semiconductor device according to a comparative example.

FIG. 14 is a schematic sectional view of a memory cell of a semiconductor device of a second embodiment.

FIGS. 15-19 are sectional views illustrating a process for manufacturing the semiconductor device according to the second embodiment.

FIGS. 20-21 are sectional views illustrating a process for manufacturing a semiconductor device according to a first modification of the second embodiment.

FIG. 22 is a schematic sectional view of a memory cell of a semiconductor device according to a second modification of the second embodiment.

FIG. 23 is a schematic sectional view of a memory cell of a semiconductor device according to a third modification of the second embodiment.

FIGS. 24-30 are sectional views illustrating a process for manufacturing a semiconductor device according to a third embodiment.

### DETAILED DESCRIPTION

A semiconductor device capable of improving a write characteristic and a manufacturing method of the same are provided.

In general, according to one embodiment, a semiconductor device includes a stacked body, a semiconductor layer, a first insulating film, a first charge storage film, a second insulating film, a second charge storage film, and a third insulating film. In the stacked body, electrode layers and insulating layers are alternately stacked in a first direction. The semiconductor layer is disposed in the stacked body along the first direction. The first insulating film extends in the first direction and is disposed between the stacked body and the semiconductor layer in a second direction crossing the first direction. The first charge storage film extends in the first direction and is disposed between the stacked body and the first insulating film in the second direction. The second insulating film is disposed between the insulating layers and the first charge storage film in the second direction. The second charge storage film is disposed between the electrode layers and the first charge storage film in the second direction and in contact with the second insulating film in the first direction. The third insulating film is disposed between the electrode layer and the second charge storage film in the second direction. The second charge storage film is an oxide film, a nitride film, or an oxynitride film, containing at least one of hafnium (Hf), aluminum (Al), and zirconium (Zr).

Hereinafter, embodiments according to the present invention will be described with reference to the drawings. The present invention is not limited by the present embodiments. The drawings are schematic or conceptual, and ratios of parts or the like shown in the drawings are not necessarily the same as the actual ones. In the specification and the drawings, the same elements as those described already with respect to the previously described drawing are denoted by the same signs and detailed description thereof is appropriately omitted.

### First Embodiment

A semiconductor device of a first embodiment is a three-dimensional NAND flash memory.

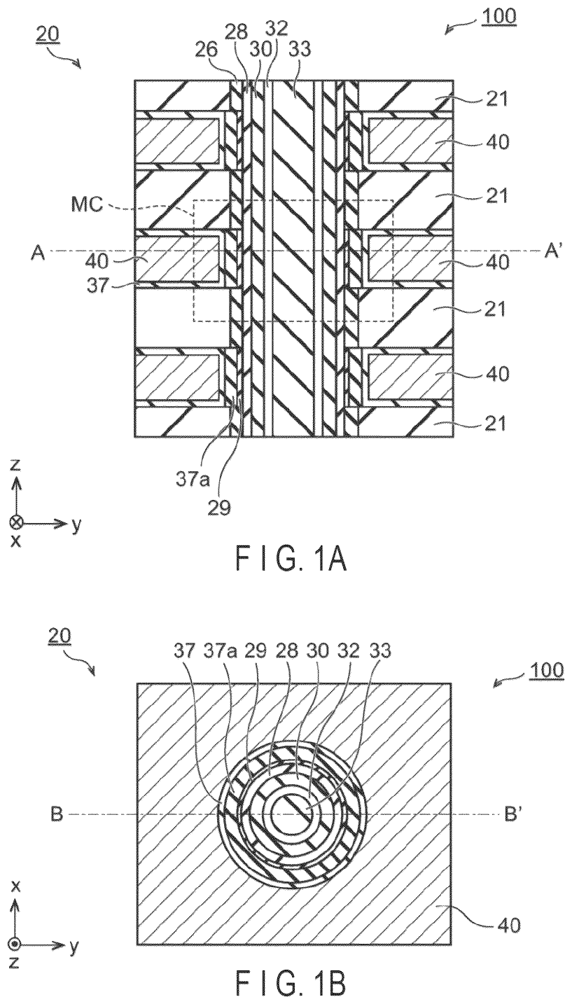

FIG. 1A and FIG. 1B are schematic sectional views of a memory cell array 100 of the semiconductor device of the first embodiment. FIG. 1A and FIG. 1B illustrate a cross section of a plurality of memory cells MC in one memory string in the memory cell array 100.

FIG. 1A is a yz sectional view of the memory cell array 100. FIG. 1A is a BB′ cross section of FIG. 1B. FIG. 1B is an xy sectional view of the memory cell array 100. FIG. 1B is an AA′ cross section of FIG. 1A. In FIG. 1A, an area surrounded by a broken line represents one memory cell MC.

As illustrated in FIG. 1A and FIG. 1B, the memory cell array 100 includes a plurality of word lines 40, a semiconductor layer 32, a plurality of insulating layers 21, a tunnel insulating film 30, a charge storage film 28, a plurality of charge storage films 29, a plurality of block insulating films 37a, a plurality of block insulating films 37, a core insulating film 33, and a cover film 26. The plurality of word lines 40 and the plurality of insulating layers 21 form a stacked body 20.

The memory cell array 100 is provided, for example, on a semiconductor substrate (not shown). The semiconductor substrate includes a surface parallel to an x direction and a y direction.

The word lines 40 and the insulating layers 21 are alternately stacked in a z direction on the semiconductor substrate. The word lines 40 are disposed separately in the z direction. The word lines 40 are repeatedly disposed in the z direction separated from each other. The plurality of word lines 40 and the plurality of insulating layers 21 form the stacked body 20. The word lines 40 function as a control electrode of a memory cell transistor.

The word line 40 is a planar conductor. The word line 40 is, for example, metal, metal nitride, metal carbide, or a semiconductor. The word line 40 is, for example tungsten (W). A thickness in the z direction of the word line 40 is, for example, 5 nm or more and 20 nm or less.

The insulating layer 21 separates two word lines 40. The insulating layer 21 electrically separates two word lines 40.

The insulating layer 21 is, for example, an oxide, an oxynitride, or a nitride. The insulating layer 21 is, for example, silicon oxide. A thickness in the z direction of the insulating layer 21 is, for example, 5 nm or more and 20 nm or less.

The semiconductor layer 32 is provided in the stacked body 20. The semiconductor layer 32 extends in the z direction. The semiconductor layer 32 extends in a direction vertical to the surface of the semiconductor substrate.

The semiconductor layer 32 is provided through the stacked body 20. The semiconductor layer 32 is surrounded by the plurality of word lines 40. The semiconductor layer 32 is cylindrical, for example. The semiconductor layer 32 functions as a channel of the memory cell transistor.

The semiconductor layer 32 is, for example, a polycrystalline semiconductor. The semiconductor layer 32 is, for example, polycrystalline silicon.

The tunnel insulating film 30 is provided between the semiconductor layer 32 and the word line 40. The tunnel insulating film 30 is provided between the semiconductor layer 32 and the plurality of word lines 40. The tunnel insulating film 30 is provided between the semiconductor layer 32 and the charge storage films 29. The tunnel insulating film 30 is provided between the semiconductor layer 32 and the charge storage film 28.

The tunnel insulating film 30 has a function of allowing charges to pass through or blocking charges from passing through according to a voltage applied between the word lines 40 and the semiconductor layer 32.

The tunnel insulating film 30 contains silicon (Si) and oxygen (O), for example. The tunnel insulating film 30 contains silicon (Si), oxygen (O), and nitrogen (N), for example.

The tunnel insulating film 30 contains silicon oxide or silicon oxynitride. The tunnel insulating film 30 is, for example, a stacked film of a silicon oxide film, a silicon oxynitride film, and a silicon oxide film.

A thickness in the y direction of the tunnel insulating film 30 is, for example, 3 nm or more and 8 nm or less.

The charge storage film 28 is provided between the tunnel insulating film 30 and the charge storage films 29. The charge storage film 28 is provided between the tunnel insulating film 30 and the insulating layers 21. The charge storage film 28 is in contact with the charge storage films 29.

The charge storage film 28 functions as a seed film when forming the charge storage films 29 by vapor phase epitaxy.

The charge storage film 28 contains silicon (Si) and nitride (N). The charge storage film 28 contains, for example, silicon nitride. The charge storage film 28 is, for example, a silicon nitride film.

The charge storage film 28 contains silicon (Si), nitride (N), and oxygen (O), for example. The charge storage film 28 contains, for example, silicon oxynitride.

A thickness in the y direction of the charge storage film 28 is, for example, 1 nm or more and 5 nm or less.

The charge storage films 29 are provided between the tunnel insulating film 30 and the word lines 40. The charge storage films 29 are provided between the tunnel insulating film 30 and the block insulating films 37. The plurality of charge storage films 29 are separated from each other. Between the two charge storage films 29 adjacent to each other in the z direction, the insulating layer 21 or the cover film 26 is provided.

The charge storage films 29 have a function of trapping and storing charges. The charges are electrons, for example. According to an amount of the charges stored in the charge storage films 29, a threshold voltage of the memory cell transistor changes. By utilizing the change of the threshold voltage, one memory cell MC can store data.

For example, since the threshold voltage of the memory cell transistor changes, a voltage with which the memory cell transistor is turned on changes. For example, when a state of a high threshold voltage is defined as data “0” and a state of a low threshold voltage is defined as data “1”, the memory cell MC can store 1-bit data of “0” and “1”.

The charge storage films 29 have a relative dielectric constant higher than that of the charge storage film 28. The charge storage films 29 are, for example, high-k films containing a high-k material.

The charge storage films 29 are oxide films, nitride films, or oxynitride films containing at least one of hafnium (Hf), aluminum (Al), and zirconium (Zr). The charge storage film 29 may be oxide films, nitride films, or oxynitride films containing two or more of hafnium (Hf), aluminum (Al), and zirconium (Zr). A film having such a composition may be referred to as a “high-k film”. The oxynitride film contains 1% or more and 20% or less of nitrogen (N).

The block insulating films 37a are provided between the charge storage films 29 and the block insulating films 37.

The block insulating films 37a have a function of blocking a current flowing between the charge storage films 29 and the word lines 40.

The block insulating films 37a contain silicon oxide, for example. The block insulating films are, for example, silicon oxide films.

The block insulating films 37 are provided between the block insulating films 37a and the word lines 40. The block insulating films 37 are in contact with the insulating layers 21 in the z direction.

The block insulating films 37 have a function of blocking the current flowing between the charge storage films 29 and the word lines 40.

The block insulating films 37 contain aluminum oxide, for example. The block insulating films 37 are, for example, aluminum oxide layers.

The core insulating film 33 is provided in the stacked body 20. The core insulating film 33 extends in the z direction. The core insulating film 33 is provided through the stacked body 20. The core insulating film 33 is surrounded by the semiconductor layer 32. The core insulating film 33 is surrounded by the plurality of word lines 40. The core insulating film 33 is columnar. The core insulating film 33 is cylindrical, for example.

The core insulating film 33 is, for example, an oxide, an oxynitride, or a nitride. The core insulating film 33 contains silicon oxide, for example. The core insulating film 33 is, for example, a silicon oxide layer.

The cover film 26 is provided between the charge storage film 28 and the insulating layers 21. The cover film 26 is in contact with the charge storage film 28 and the insulating layers 21. The cover film 26 contains silicon and oxygen, for example. The cover film 26 is, for example, a silicon oxide film.

A thickness in the y direction of the cover film 26 is, for example, 3 nm or more and 8 nm or less.

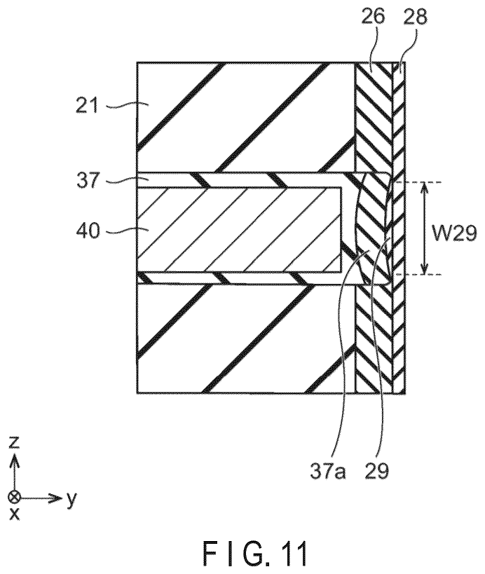

A detailed configuration of the charge storage films 29 will be described later with reference to FIG. 11. Details of a composition of the charge storage films 29 will be described later.

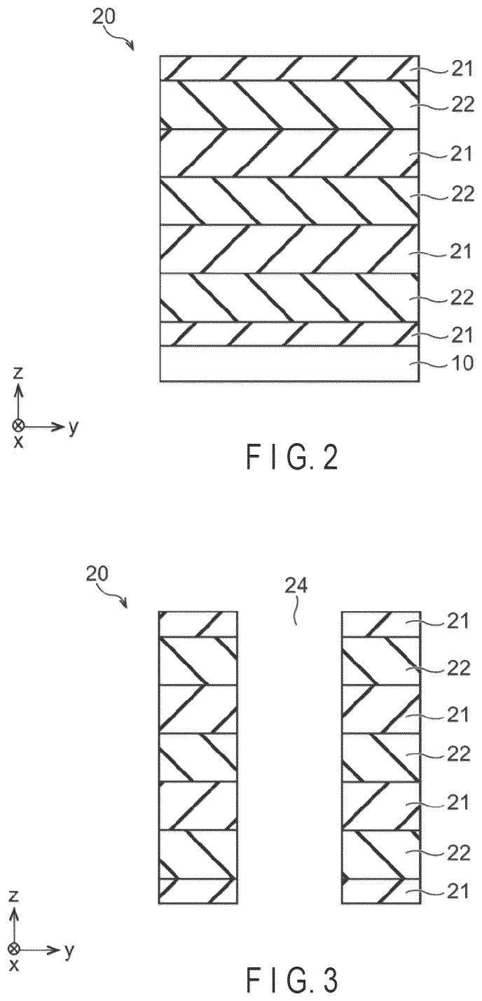

The semiconductor device of the first embodiment will be described with reference to FIG. 2 to FIG. 11. The semiconductor device of this embodiment is manufactured by a method indicated below for example. First, as illustrated in FIG. 2, the insulating layers 21 and sacrificial layers 22 are alternately stacked on a semiconductor substrate 10. Thus, the stacked body 20 stacked in the z direction (an up-down direction in the figure) is formed. The insulating layers 21 are silicon oxide layers for example. The sacrificial layers 22 are silicon nitride layers for example.

The insulating layers 21 and the sacrificial layers 22 are formed by a CVD (chemical vapor deposition) method for example. Some of the insulating layers 21 become interlayer insulating layers.

Next, as illustrated in FIG. 3, a memory hole 24 along the z direction is formed in the stacked body 20. In FIG. 3 and the subsequent drawings, the semiconductor substrate 10 is omitted. The memory hole 24 passes through the stacked body 20 of the insulating layers 21 and the sacrificial layers 22. The memory hole 24 is formed using a lithography method and an RIE (reactive ion etching) method for example.

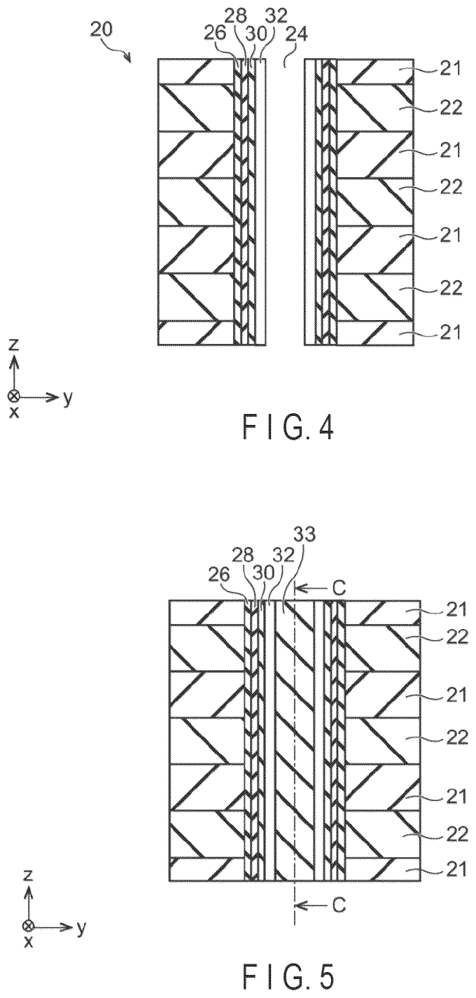

Next, as illustrated in FIG. 4, on an inner wall of the memory hole 24, a silicon oxide film is formed as a cover film 26 that has a function of a stopper film. On the cover film 26, as the charge storage film 28 to be a part of the charge storage film, a silicon oxide film having a thickness of 2 nm for example is formed. On the charge storage film 28, as the tunnel insulating film 30, a silicon oxynitride film having a thickness of 5 nm for example is formed. On the tunnel insulating film 30, the semiconductor layer 32 having a thickness of 7 nm for example is formed. The cover film 26, the charge storage film 28, and the tunnel insulating film 30 are formed by the CVD method for example. As a material of the semiconductor layer 32, polysilicon is typically used. However, from a viewpoint of surface roughness, a method of performing crystallization by forming amorphous silicon at a low temperature (about 500° C. for example) and then executing heat treatment at 800° C. or higher for example is used. Note that materials of the cover film 26, the charge storage film 28, and the tunnel insulating film 30 are examples, and are not limited in particular as long as the materials can realize a structure of the semiconductor device of the embodiment described in FIG. 1A, FIG. 1B, and following FIG. 11.

Next, as illustrated in FIG. 5, the memory hole 24 is filled with the core insulating film 33. The core insulating film 33 is, for example, a silicon oxide film. In the following description, since cross sections are symmetrical to a center line C-C illustrated in FIG. 5, the cross section on a left side of the center line C-C will be described. Note that in the following drawings, the tunnel insulating film 30, the semiconductor layer 32, and the core insulating film 33 are not displayed.

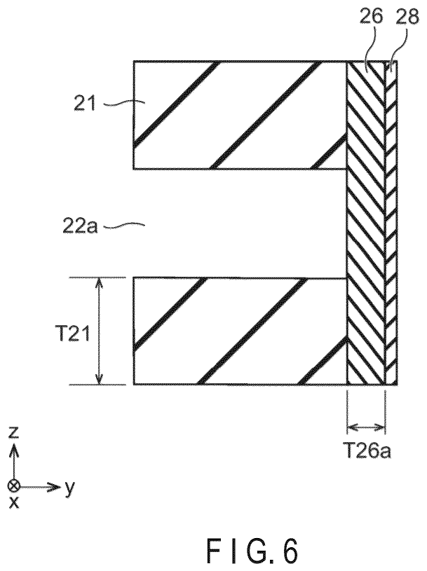

Thereafter, grooves passing through the stacked body 20 are opened around the memory hole 24, by removing the sacrificial layers 22. By removing the sacrificial layers 22, the cover film 26 is exposed. For removal of the sacrificial layers 22, a heated phosphoric acid chemical solution is normally used. By the chemical solution treatment, voids 22a are generated at sites of the removed silicon oxide layers. The voids 22a tracing a shape of the original sacrificial layers 22 are generated (see FIG. 6).

A thickness T21 in the z direction of the insulating layer 21 is 20 nm, for example. A thickness T26a in the y direction of the cover film 26 is 7.0 nm, for example.

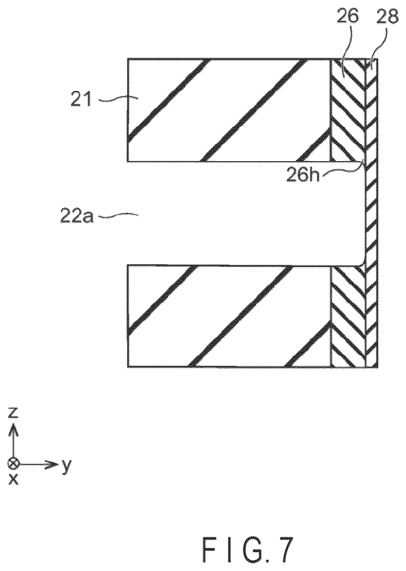

Next, as illustrated in FIG. 7, the cover film 26 is partially removed by a hydrofluoric acid (HF) chemical solution diluted to about 0.5%. Thus, a part of the charge storage film 28 is exposed in the void 22a.

By the diluted hydrofluoric acid (HF) chemical solution, a surface of the insulating layers 21 is also partially removed. Since an etching rate of the cover film 26 is lower than an etching rate of the insulating layers 21, a hem portion 26h in contact with the charge storage film 28 is formed on the cover film 26.

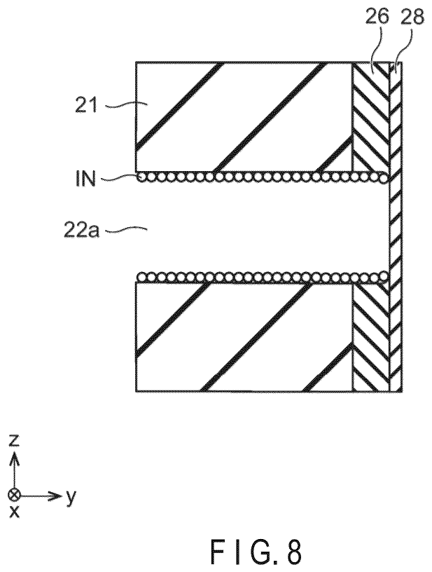

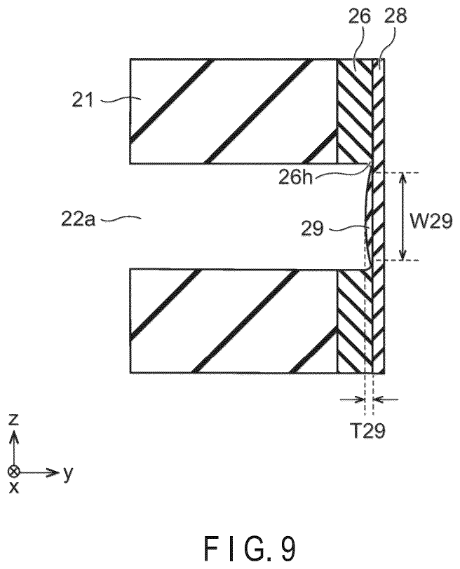

Next, as illustrated in FIG. 8, an inhibitor IN is supplied. The inhibitor IN is deposited on the surface of the insulating layers 21 and the cover film 26. The inhibitor IN inhibits adsorption of a precursor of the charge storage films 29 to the insulating layers 21 and the cover film 26 for later selective growth of the charge storage films 29. In FIG. 9 and the subsequent drawings, the inhibitor IN is omitted. In addition, a process of removing the inhibitor IN may be added, or the inhibitor may not be necessarily used when the charge storage films 29 can be formed selectively on the surface of the charge storage film 28 in a subsequent process.

Next, as illustrated in FIG. 9, with an exposed surface of the charge storage film 28 as a base point, the selective growth of the charge storage films 29 using ASD (area selective deposition) method, is performed. The charge storage films 29 have the relative dielectric constant higher than that of the charge storage film 28. The charge storage films 29 are, for example, the high-k films described above. In this example, the charge storage films 29 are HfN, HfO₂, or HfON, for example.

Film formation (selective growth) of HfN as the charge storage films 29 is performed by an ALD (atomic layer deposition) method in which one cycle includes supplying HfCl₄, performing vacuum drawing/purging, and supplying NH₃. HfCl₄ is supplied at a treatment temperature from 200° C. to 450° C., for example. NH₃ is supplied at the treatment temperature from 200° C. to 450° C., for example.

Note that HfO₂ may be formed as the charge storage films 29 by forming HfN and then oxidating HfN. Oxidation treatment is, for example, dry oxidation, wet oxidation, or radical oxidation or the like. In addition, as the charge storage films 29, HfON may be formed. In a case of forming HfON from HfN, for example, it is performed by appropriately changing a temperature and/or time of the oxidation treatment as a parameter so as to attain a desired N concentration. Further, the composition of the charge storage films 29 is not limited to HfN, HfO₂, or HfON as described later.

Charge storage films of the embodiment include the charge storage film 28 and the charge storage films 29. By the treatment, the charge storage films 29 are formed to have a thickness of about 1 nm to about 2 nm in the y direction. Thus, in the y direction of the void 22a, the thickness in the y direction of the charge storage film is a sum of the thickness (about 1 nm to about 3 nm) of the charge storage film 28 and the thickness (about 1 nm to about 2 nm) of the charge storage film 29. However, the charge storage film in an area where the charge storage film 29 is not provided is the charge storage film 28, and the thickness is about 1 nm to about 3 nm. That is, while the charge storage film 28 continues in a direction (z direction) in which the semiconductor layer 32 extends, the charge storage film 29 is divided in the z direction by the cover film 26. Thus, a pseudo division structure of the charge storage film is formed.

Here, as illustrated in FIG. 9, an upper end and a lower end of the charge storage film 29 are sometimes not easily formed thick as compared with a center portion. This happens because the inhibitor IN is less likely to be adhered to the surface of the charge storage film 28 near the cover film 26 in the case of using the inhibitor IN which obstructs the adsorption of the precursor to the insulating layers 21 and the cover film 26 when performing the selective growth of the charge storage films 29. Further, even in the case of not using the inhibitor IN, a silicon raw material is sometimes not easily adsorbed at the upper end and the lower end of the charge storage film 29 as compared to the center portion.

The surface of the charge storage film 29 facing the stacked body 20 has a convex shape toward the stacked body 20. A thickness T29 in the y direction of the charge storage film 29 is 1 nm to 2 nm, for example. A width W29 indicates a width in the z direction of the charge storage film 29.

Further, the charge storage film 29 is disposed so as to project in the y direction from the charge storage film 28 toward the stacked body 20. Thus, the charge storage film 28 does not have unevenness on the surface facing the semiconductor layer 32. That is, the surface of the charge storage film 28 facing the semiconductor layer 32 is substantially flat. Note that the thickness in the y direction of the charge storage film 28 is almost constant along the z direction. In an area where the charge storage film 29 is provided, the charge storage film is thicker in the y direction.

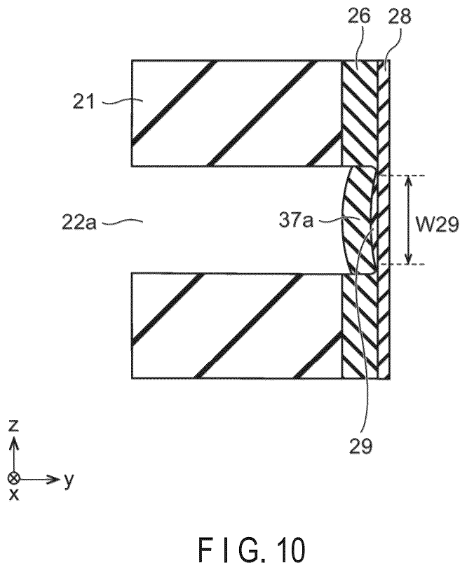

Next, as illustrated in FIG. 10, the block insulating film 37a is selectively formed on the charge storage film 29. When the charge storage film 29 is HfON and HfAlON for example, a surface layer OH radical is dissociated by crystallization (an H concentration in the film becomes 1.0×10¹⁹ to 1.0×10²¹ atoms/cm³ for example). Thus, in a process using the inhibitor similarly to the case of forming a silicon nitride film on a silicon nitride film, a silicon nitride film can be formed on the charge storage film 29. Thereafter, by oxidating the formed silicon nitride film, the formed silicon nitride film is converted to a silicon oxide film. Thus, the block insulating film 37a including the silicon oxide film is selectively formed on the charge storage film 29.

A thickness in the y direction of the block insulating film 37a is 5 nm to 7 nm, for example.

Next, as illustrated in FIG. 11, the block insulating film 37 containing aluminum oxide for example is formed so as to cover a bottom and a side of the void 22a. Barrier metal containing TiN for example may be formed so as to cover the block insulating film 37.

Next, the voids 22a are filled with a wiring material such as W (tungsten) to form the word lines 40, and the semiconductor device is completed.

As described for the pseudo division structure of the charge storage film, the sum of the thicknesses in the y direction of the charge storage film 28 and the charge storage film 29 is larger than the thickness in the y direction of the charge storage film 28.

As above, in the first embodiment, the sum of the thicknesses in the y direction of the charge storage film 28 and the charge storage film 29 is larger than the thickness in the y direction of the charge storage film 28. Thus, a write characteristic can be improved.

In addition, while the charge storage film 28 continues along the direction (2 direction) in which the semiconductor layer 32 to be a channel extends, the charge storage film 29 is divided in the direction (z direction) in which the semiconductor layer 32 to be the channel extends, by the insulating layers 21 and the cover film 26 so that charges can be suppressed from leaking in the direction (z direction) in which the semiconductor layer 32 to be the channel extends. Thus, according to the present embodiment, degradation of a charge retention performance can be suppressed.

Further, the charge storage film 29 is a high-k film. Thus, a function of the charge storage film itself can be improved. As a result, the charge storage film can be thinned, and a write/erase characteristic (W/E characteristic) can be improved.

Other examples of the composition of the charge storage film 29 will be described.

In a process illustrated in FIG. 9, supply of HfCl₄ may be changed or added. To HfCl₄, AlCl₃ and/or ZrCl₄ or the like may be supplied or added. Thus, for example, the charge storage film 29 containing Hf and Al, the charge storage film 29 containing Hf and Zr, the charge storage film 29 containing Hf, Al, and Zr, or the charge storage film 29 containing Al and Zr or the like may be formed.

Formation of the charge storage film 29 containing HfAlN will be described. The charge storage film 29 is formed by the ALD method in which one cycle includes supplying HfCl₄, performing vacuum drawing/purging, supplying NH₃, performing vacuum drawing/purging, supplying AlCl₃, performing vacuum drawing/purging, and supplying NH₃ in this order. In addition, the charge storage film 29 containing HfAlN may be formed by the ALD method in which one cycle includes supplying HfCl₄, performing vacuum drawing/purging, supplying AlCl₃, performing vacuum drawing/purging, and supplying NH₃ in this order. Further, in the two flow examples described above, the ALD method in which orders of supplying HfCl₄ and AlCl₃ are changed, may be performed. In addition, the ALD method using N₂H₄ instead of NH₃ as a nitriding agent may be performed.

Note that HfAlO₂ may be formed as the charge storage film 29 by forming HfAlN and then oxidating HfAlN. In addition, for example, by parameter change of the oxidation treatment, HfAlON may be formed as the charge storage film 29.

Formation of the charge storage film 29 containing HfZrN will be described. The charge storage film 29 is formed by the ALD method using ZrCl₄ instead of AlCl₃ in the four film formation flows described above for the charge storage film 29 containing HfAlN.

Note that HfZrO₂ may be formed as the charge storage film 29 by forming HfZrN and then oxidating HfZrN. In addition, for example, by the parameter change of the oxidation treatment, HfZrON may be formed as the charge storage film 29.

Formation of the charge storage film 29 containing HfAlZrN will be described.

The charge storage film 29 is formed by the ALD method in which a step of supplying ZrCl₄, performing vacuum drawing/purging, and supplying NH₃ is inserted in the four film formation flows for the charge storage film 29 containing HfAlN. The step may be inserted at any timing after supplying NH₃ and performing vacuum drawing/purging.

Note that HfAlZrO2 may be formed as the charge storage film 29 by forming HfAlZrN and then oxidating HfAlZrN. In addition, for example, by the parameter change of the oxidation treatment, HfAlZrON may be formed as the charge storage film 29.

Formation of the charge storage film 29 containing AlZrN will be described. The charge storage film 29 is formed by the ALD method using ZrCl₄ instead of HfCl₃ in the four film formation flows described above for the charge storage film 29 containing HfAlN.

Note that AlZrO₂ may be formed as the charge storage film 29 by forming AlZrN and then oxidating AlZrN. In addition, for example, by the parameter change of the oxidation treatment, AlZrON may be formed as the charge storage film 29.

### First Comparative Example of First Embodiment

In a first comparative example, there is a case where the charge storage film 29 is not provided. The first comparative example differs from the first embodiment in that the charge storage film is flat without having the pseudo division structure. In the first comparative example, when a film thickness of the charge storage film that is a silicon nitride film is 5 nm, ISPP (write efficiency) is 0.77.

In contrast, in the first embodiment, when the charge storage film 29 is HfAlO (including 75% or less of Al for example) and the sum of the film thickness of the charge storage film 28 that is a silicon nitride film and the film thickness of the charge storage film 29 is 3 nm, the ISPP (write efficiency) is 0.90 V/V or greater. Thus, the film thickness of the charge storage film including the charge storage films 28 and 29 can be reduced, and the characteristic of the ISPP or the like can be improved.

### Second Comparative Example of First Embodiment

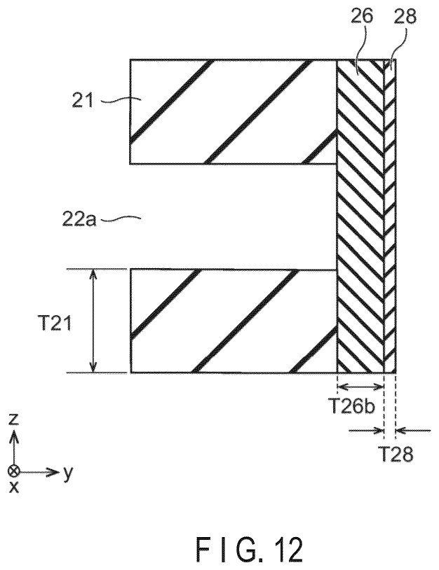

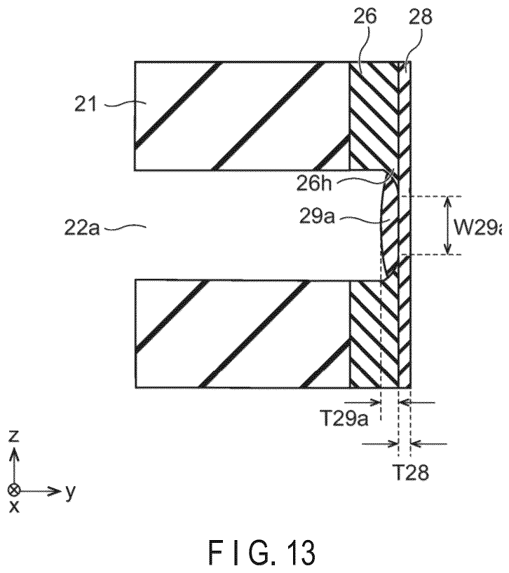

A semiconductor device according to a second comparative example will be described with reference to FIG. 12 to FIG. 13. The second comparative example differs from the first embodiment in that a charge storage film 29a that is a silicon nitride film, is provided instead of the charge storage film 29.

First, similarly to FIG. 2 to FIG. 5 of the first embodiment, the stacked body 20 and the memory hole 24 are formed, and the cover film 26, the charge storage film 28, the tunnel insulating film 30, the semiconductor layer 32, and the core insulating film 33 are formed inside the memory hole 24.

Next, as illustrated in FIG. 12 corresponding to FIG. 6 of the first embodiment, the sacrificial layers 22 are removed.

A thickness T26b in the y direction of the cover film 26 is 9.5 nm, for example. A thickness T28 in the y direction of the charge storage film 28 is 2.0 nm, for example.

Next, as illustrated in FIG. 13, the cover film 26 is partially removed (similarly to FIG. 7 of the first embodiment), and the selective growth of the charge storage film 29a is performed with the exposed surface of the charge storage film 28 (seed film) as a base point. The charge storage film 29a is, for example, a silicon nitride film. In addition, in an example illustrated in FIG. 13, a cross-sectional shape of the charge storage film 29a is a convex lens shape. This leads to degradation of the write/erase characteristic (W/E characteristic).

A thickness T29a in the y direction of the charge storage film 29a is 3.5 nm, for example. A width W29a indicates a width in the z direction of the charge storage film 29a.

Thereafter, by a process similar to the process illustrated in FIG. 11 in the first embodiment, the semiconductor device is completed.

In the embodiment, as compared to the second comparative example, since the charge storage film 29 is a high-k film, charge trapping performance is high. Thus, the charge storage film 29 can be made thinner than the charge storage film 29a.

In FIG. 13, when the thickness T28 of the charge storage film 28 is 2 nm, the film thickness T26b of the cover film 26 illustrated in FIG. 12 needs to be 9.5 nm. Since a function as a stopper of the phosphoric acid chemical solution is needed for the cover film 26, film quality close to a thermal oxide film is needed for the cover film 26, and a selection ratio of a hydrofluoric acid (HF) chemical solution with the insulating layer 21 is generated. Note that the insulating layer 21 is TEOS (Tetra-ethoxy silane), for example. Thus, since a trailing amount increases (the hem portion 26h becomes longer in the z direction as compared to embodiment) in proportion to the thickness T26b of the cover film 26, the width W29a is reduced.

In the embodiment, when the charge storage film 29 having the thickness T29 of 1 nm illustrated in FIG. 9 has the charge trapping performance equivalent to that of the charge storage film 29a having the thickness T29a of 3.5 nm illustrated in FIG. 13, the thickness T26a of the cover film 26 illustrated in FIG. 6 can be reduced from 9.5 nm of the thickness T26b to 7.0 nm. Thus, the hem portion 26h of the cover film 26 illustrated in FIG. 9 can be shortened in the z direction, and the width W29 can be widened 1.2 times, for example, with respect to the width W29a. As a result, the cross-sectional shape in the convex lens shape of the charge storage film 29 is suppressed, and the write/erase characteristic (W/E characteristic) can be improved. Further, since the thickness T26 of the cover film 26 can be reduced, an interval (margin) between the memory holes 24 does not need to be widened at the time of design.

Further, since the charge storage film 29 has the high charge trapping performance, a possibility of side leakage of charges to an adjacent cell direction increases. Thus, the charge storage film 29 is desirably used together with a division structure (the pseudo division structure or a complete division structure, which is described below) of the charge storage film.

### Second Embodiment

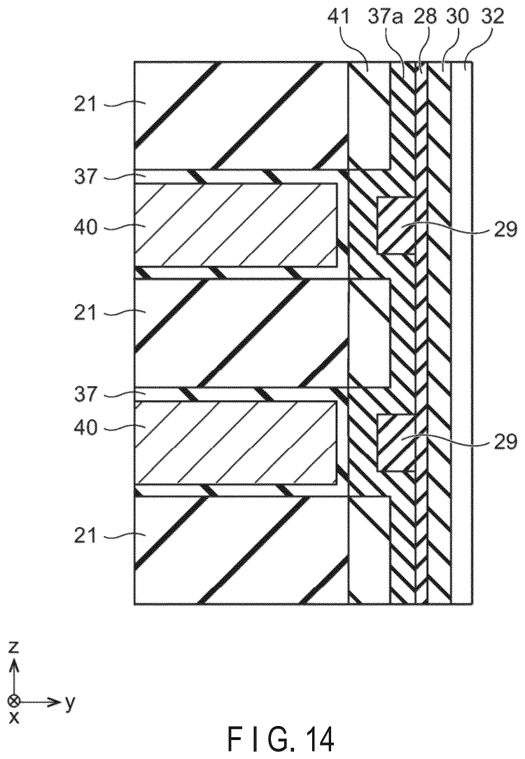

FIG. 14 is a schematic sectional view of the memory cell array 100 of a semiconductor device of a second embodiment. The second embodiment differs from the first embodiment in that the pseudo division structure of the charge storage film is formed not from the side of the stacked body 20 but from the side of the memory hole 24.

In the following description, since cross sections are symmetrical to the center line C-C illustrated in FIG. 5, the cross section on the left side of the center line C-C will be described. Note that in the following drawings, the core insulating film 33 is not displayed.

In an example illustrated in FIG. 14, the cover film 26 is not provided as compared with the first embodiment described with reference to FIG. 1A.

The block insulating film 37a is provided so as to extend continuously in the z direction along the charge storage film 28 and the charge storage films 29.

The memory cell array 100 further includes an insulating film 41. The insulating film 41 is provided between the insulating layer 21 and the block insulating film 37a. The insulating film 41 contains silicon oxide, for example.

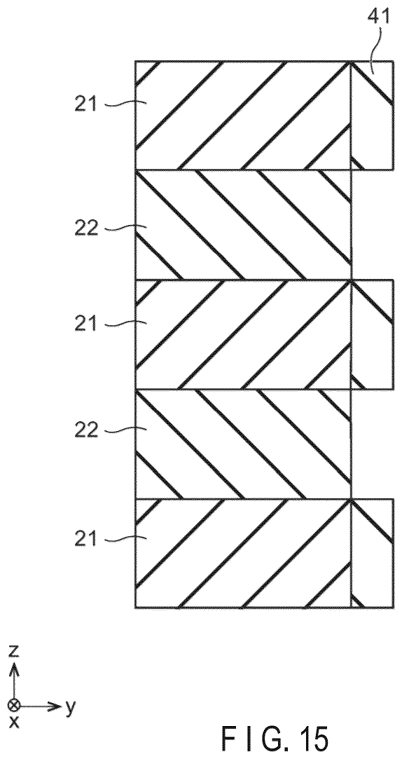

The semiconductor device of the second embodiment will be described with reference to FIG. 15 to FIG. 19. A process illustrated in FIG. 15 is performed after the processes similar to those in FIG. 2 and FIG. 3.

After forming the memory hole 24 (see FIG. 3), as illustrated in FIG. 15, the insulating film 41 is selectively formed on the insulating layer 21 on an inner side face of the memory hole 24. In more detail, the insulating film 41 is selectively grown from the insulating layer 21 (with the surface of the insulating layer 21 as a base point). Thus, an opening of the insulating film 41 is formed in an area corresponding to the sacrificial layer 22.

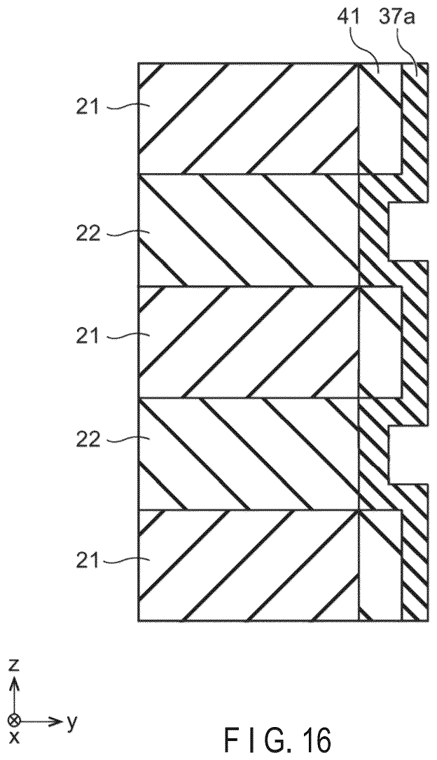

Next, as illustrated in FIG. 16, the block insulating film 37a is formed on the sacrificial layers 22 and the insulating film 41.

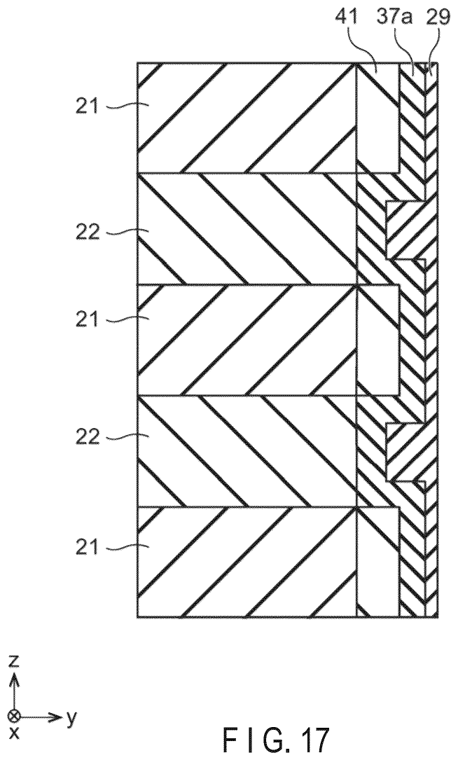

Next, as illustrated in FIG. 17, the charge storage film 29 is formed on the block insulating film 37a. The charge storage film 29 is formed by repeating the film formation (deposition) and etching of the charge storage film 29. In more detail, the charge storage film 29 is formed by repeating the film formation (deposition) and etching of the charge storage film 29 in-situ (in the same furnace). Thus, the charge storage film 29 is formed so that the surface becomes substantially flat. The film formation (deposition) of the charge storage film 29 is performed by the ALD method, for example. The etching of the charge storage film 29 is performed by atomic layer etching (ALE), for example.

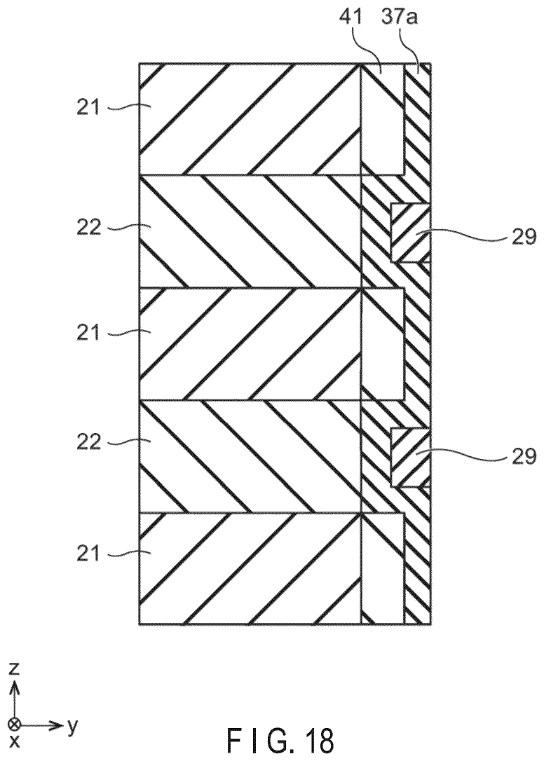

Next, as illustrated in FIG. 18, the charge storage film 29 is removed until the block insulating film 37a in the area corresponding to the insulating film 41 is exposed. The charge storage film 29 is removed by wet etching using mixed acid, for example.

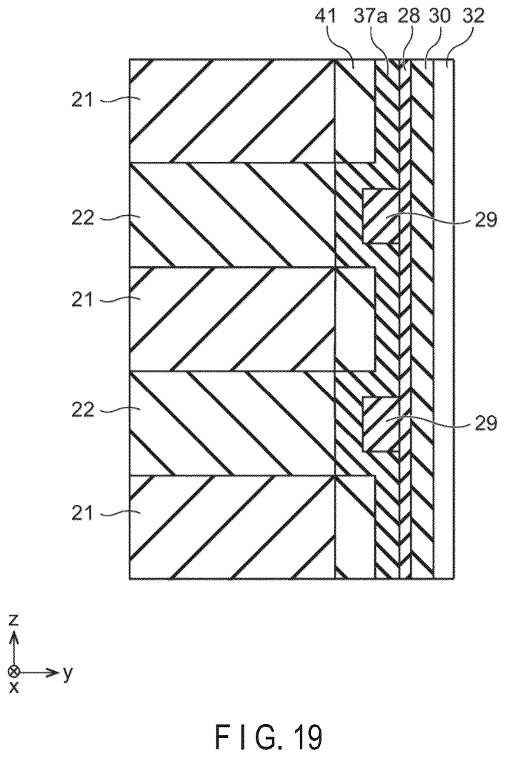

Next, as illustrated in FIG. 19, the charge storage film 28 is formed on the block insulating film 37a and the charge storage film 29, the tunnel insulating film 30 is formed on the charge storage film 28, and the semiconductor layer 32 is formed on the tunnel insulating film 30.

Thereafter, by removing the sacrificial layers 22 similarly to the process illustrated in FIG. 6 and forming the block insulating film 37 and the word lines 40 similarly to the process illustrated in FIG. 11, the semiconductor device illustrated in FIG. 14 is completed. Note that barrier metal containing TiN for example may be formed so as to cover the block insulating film 37.

In the second embodiment, the pseudo division structure of the charge storage film may be formed from the side of the memory hole 24. The semiconductor device of the second embodiment can provide an effect similar to that of the first embodiment.

In addition, as illustrated in FIG. 14, the surface of the charge storage film 29 facing the stacked body 20 is substantially flat along the z direction. The surface of the charge storage film 29 facing the semiconductor layer 32 is substantially flat along the z direction.

Further, roughness of the surface of the charge storage film 29 facing the semiconductor layer 32, and roughness of the charge storage film 28, the tunnel insulating film 30, and the semiconductor layer 32 in the area corresponding to the charge storage film 29 are each 0.5 nm or lower.

### First Modification of Second Embodiment

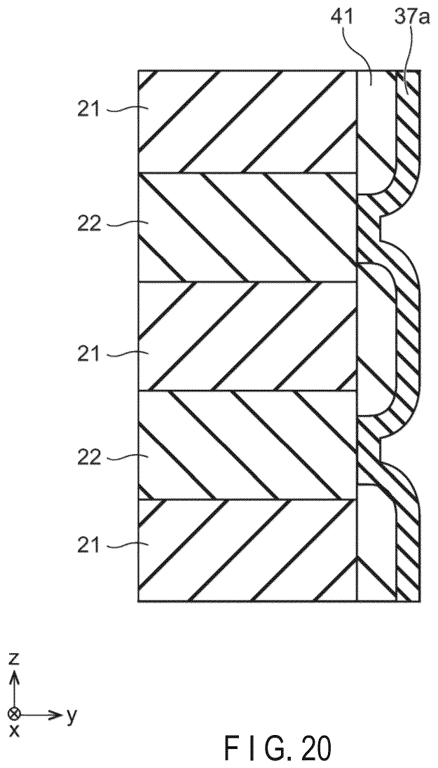

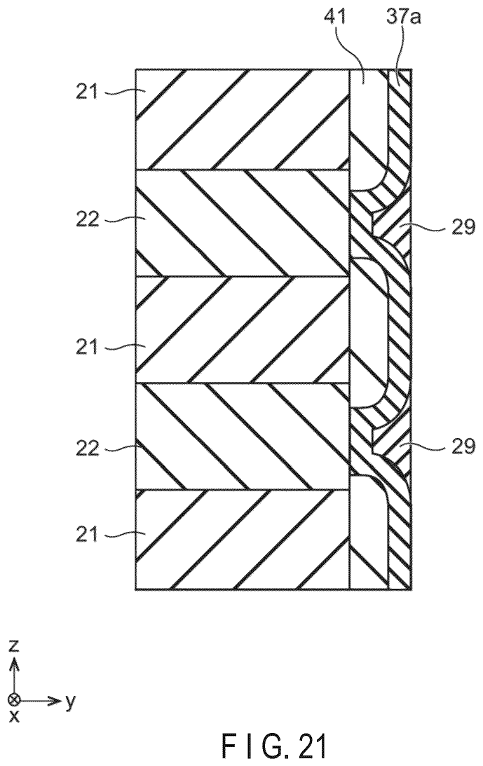

A semiconductor device according to a first modification of the second embodiment will be described with reference to FIG. 20 and FIG. 21. The first modification of the second embodiment differs from the second embodiment in that a frontage (edge) of the opening of the insulating film 41 is not rectangular.

A process illustrated in FIG. 20 corresponds to the process illustrated in FIG. 16 in the second embodiment. As illustrated in FIG. 20, it is sometimes difficult to form the frontage of the opening of the insulating film 41 to be rectangular, due to trailing of the insulating film 41 or the like.

A process illustrated in FIG. 21 corresponds to the process illustrated in FIG. 18 in the second embodiment. As illustrated in FIG. 21, the charge storage film 29 is formed so that the surface becomes substantially flat, that is, the surface becomes flush with the surface of the block insulating film 37a.

In the first modification of the second embodiment, the frontage (edge) of the opening of the insulating film 41 may not be rectangular. The semiconductor device of the first modification of the second embodiment can provide an effect similar to that of the second embodiment.

### Second Modification of Second Embodiment

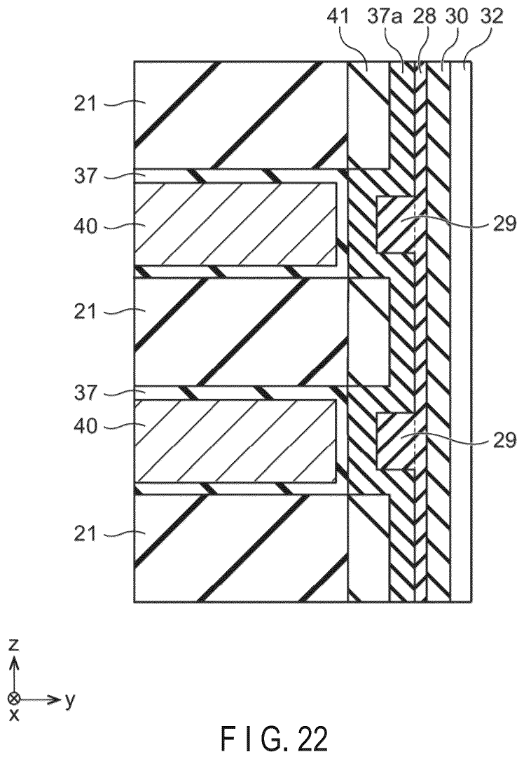

FIG. 22 is a schematic sectional view of the memory cell array 100 of a semiconductor device of a second modification of the second embodiment. The second modification of the second embodiment differs from the second embodiment in that the charge storage film 28 is a high-k film.

The charge storage film 28 is a high-k film. The charge storage film 28 is an oxide film, a nitride film, or an oxynitride film, containing at least one of hafnium (Hf), aluminum (Al), and zirconium (Zr). The charge storage film 28 may be an oxide film, a nitride film, or an oxynitride film, containing two or more of hafnium (Hf), aluminum (Al), and zirconium (Zr). The composition of the charge storage film 28 is the same as the composition of the charge storage film 29, but may be different.

In the second modification of the second embodiment, the charge storage film 28 may be a high-k film. The semiconductor device of the second modification of the second embodiment provides an effect similar to that of the second embodiment.

### Third Modification of Second Embodiment

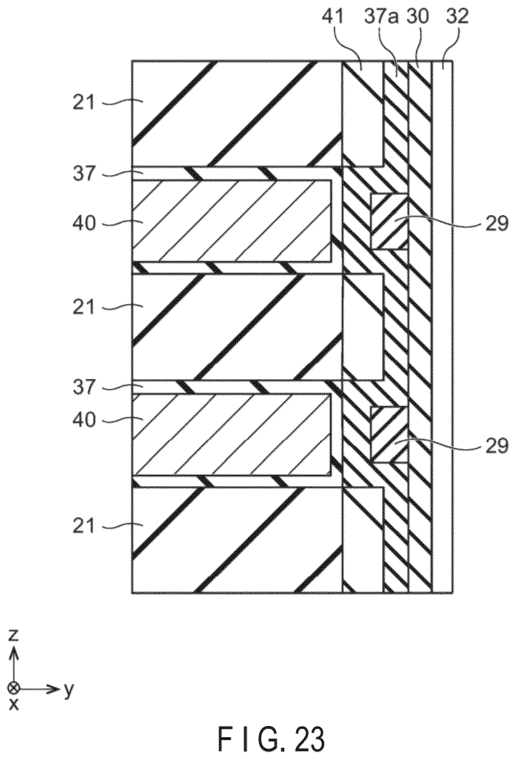

FIG. 23 is a schematic sectional view of the memory cell array 100 of a semiconductor device of a third modification of the second embodiment. The third modification of the second embodiment differs from the second embodiment in that the charge storage film 28 is not provided.

Since the charge storage film 28 is not provided, the complete division structure of the charge storage film is formed. Thus, charges can be further suppressed from leaking in the direction (z direction) in which the semiconductor layer 32 to be the channel extends. Therefore, the charge retention characteristic can be further improved.

In the third modification of the second embodiment, the charge storage film 28 may not be provided. The semiconductor device of the third modification of the second embodiment can provide an effect similar to that of the second embodiment.

### Third Embodiment

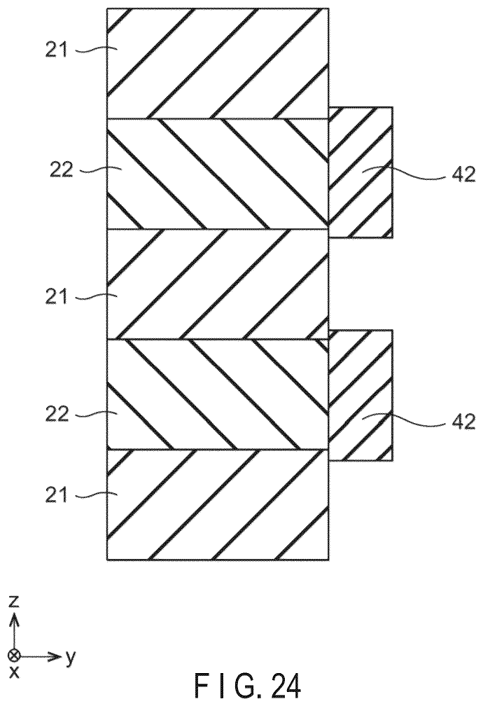

A semiconductor device according to a third embodiment will be described with reference to FIG. 24 to FIG. 30. The third embodiment differs from the second embodiment in that a formation method of the insulating film 41 is different. Processes illustrated in FIG. 24 to FIG. 30 are performed after the processes similar to those in FIG. 2 and FIG. 3.

After forming the memory hole 24 (see FIG. 3), as illustrated in FIG. 24, insulating films 42 are selectively formed on the sacrificial layers 22 on the inner side face of the memory hole 24. The insulating film 42 contains silicon oxide, for example. The insulating film 42 is formed by selectively forming a silicon nitride film on the sacrificial layer 22 and oxidating the silicon nitride film.

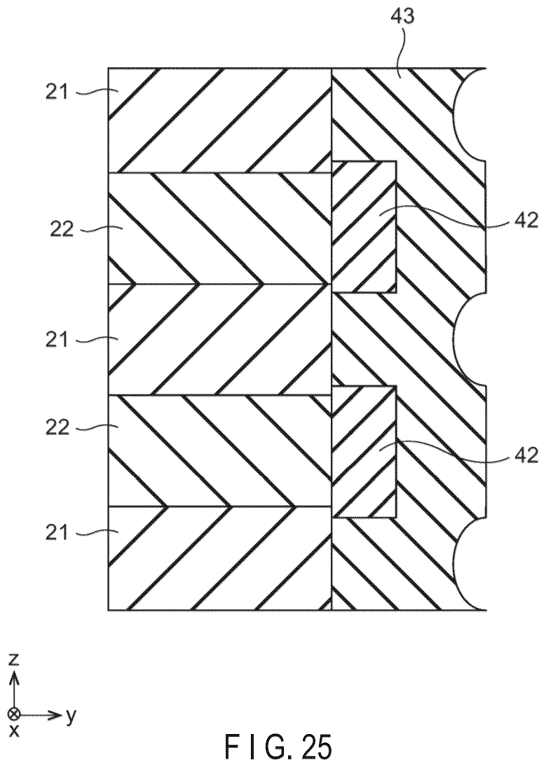

Next, as illustrated in FIG. 25, an insulating film 43 is formed on the insulating layers 21 and the insulating films 42. The insulating film 43 contains silicon nitride, for example. The insulating film 43 is formed by the ALD method, for example.

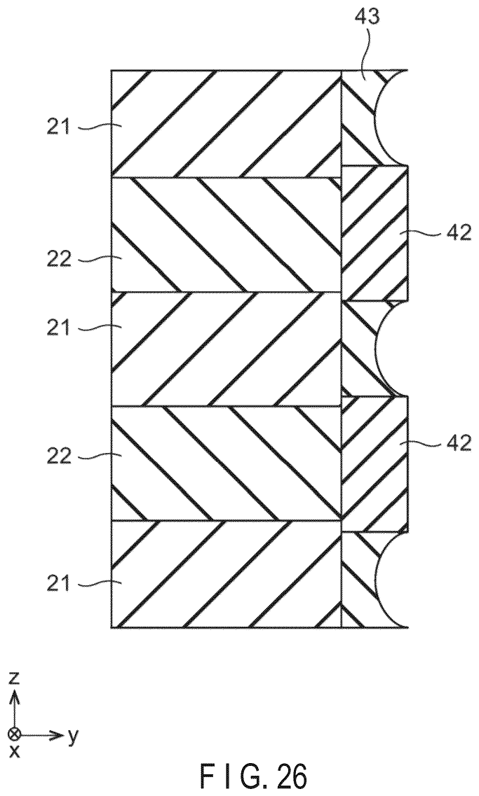

Next, as illustrated in FIG. 26, the insulating film 43 is removed until the insulating films 42 are exposed. The insulating film 43 is removed by wet etching using a heated phosphoric acid chemical solution.

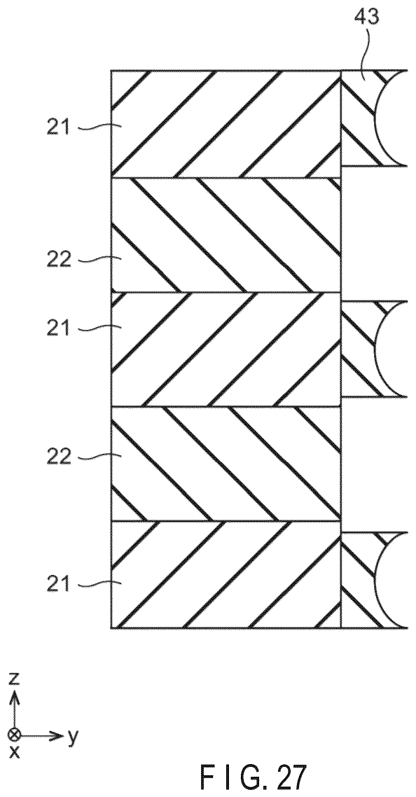

Then, as illustrated in FIG. 27, the insulating films 42 are selectively removed. The insulating films 42 are removed by wet etching using a diluted hydrofluoric acid (HF) chemical solution. Thus, the insulating film 43 remains on the insulating layers 21.

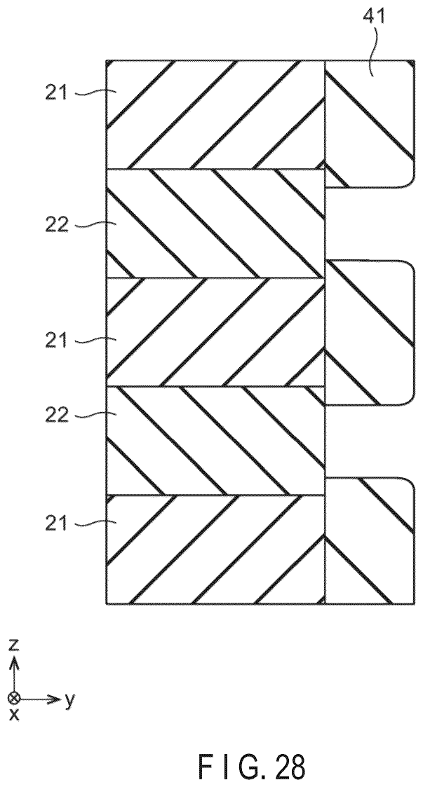

Next, as illustrated in FIG. 28, by oxidating the insulating film 43, the insulating film 41 is formed. Oxidation is, for example, radical oxidation.

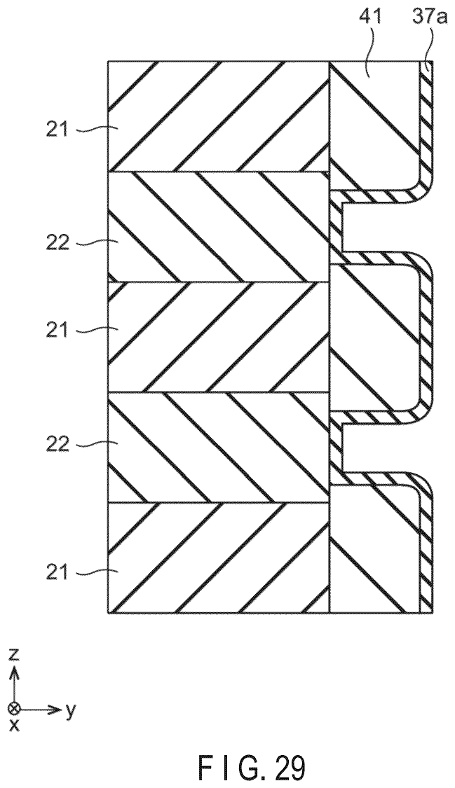

Then, as illustrated in FIG. 29, the block insulating film 37a is formed on the sacrificial layers 22 and the insulating film 41 (similarly to the process illustrated in FIG. 16 in the second embodiment).

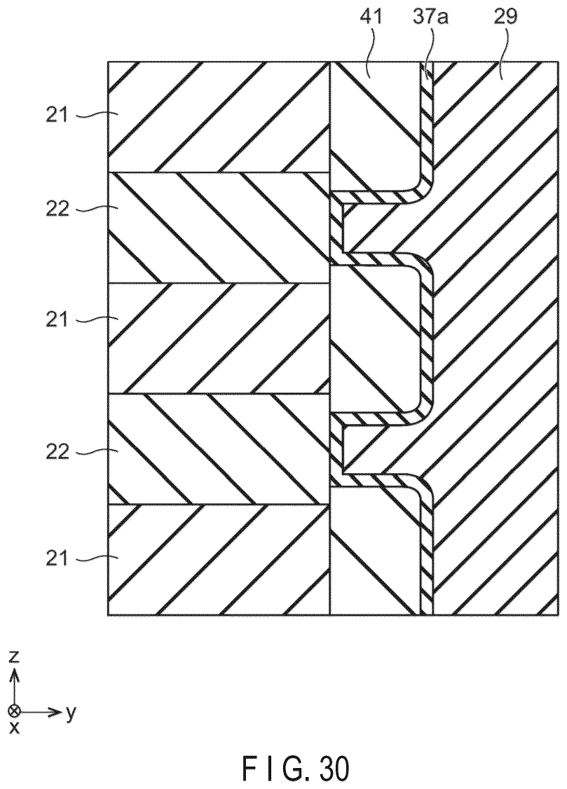

Next, as illustrated in FIG. 30, the charge storage film 29 is formed on the block insulating film 37a (similarly to the process illustrated in FIG. 17 in the second embodiment).

Thereafter, by processes similar to the processes of FIG. 18 and the subsequent drawings in the second embodiment, the semiconductor device is completed.

In the third embodiment, the formation method of the insulating film 41 may be different. The semiconductor device of the third embodiment provides an effect similar to that of the second embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a stacked body in which electrode layers and insulating layers are alternately stacked in a first direction;
a semiconductor layer disposed in the stacked body along the first direction;
a first insulating film extending in the first direction and disposed between the stacked body and the semiconductor layer in a second direction crossing the first direction;
a first charge storage film extending in the first direction and disposed between the stacked body and the first insulating film in the second direction;
a second insulating film disposed between the insulating layers and the first charge storage film in the second direction;
a second charge storage film disposed between the electrode layers and the first charge storage film in the second direction and in contact with the second insulating film in the first direction; and
a third insulating film disposed between the electrode layers and the second charge storage film in the second direction,
wherein the second charge storage film is an oxide film, a nitride film, or an oxynitride film, containing at least one of hafnium (Hf), aluminum (Al), and zirconium (Zr).

2. The semiconductor device of claim 1, wherein the second charge storage film is the oxynitride film which contains 1% or more and 20% or less of nitrogen (N).

3. The semiconductor device of claim 1, wherein a first surface of the second charge storage film facing the stacked body has a convex shape toward the stacked body.

4. The semiconductor device of claim 1, wherein
a first surface of the second charge storage film facing the stacked body is flat along the first direction, and
a second surface of the second charge storage film facing the semiconductor layer is flat along the first direction.

5. The semiconductor device of claim 4, wherein
the second insulating film and the third insulating film are made of the same material and formed at the same time.

6. The semiconductor device of claim 1, wherein roughness of a second surface of the second charge storage film facing the semiconductor layer, and roughness of the first charge storage film, the first insulating film, and the semiconductor layer in an area corresponding to the second charge storage film, are each 0.5 nm or lower.

7. The semiconductor device of claim 1, wherein the first charge storage film contains SiN.

8. The semiconductor device of claim 1, wherein the first charge storage film is an oxide film, a nitride film, or an oxynitride film, containing at least one of hafnium (Hf), aluminum (Al), and zirconium (Zr).

9. A method of manufacturing a semiconductor device, comprising:
forming a stacked body in which sacrificial layers and insulating layers are alternately stacked in a first direction;
forming a hole extending through the stacked body in the first direction;
forming a first film of an insulator on an inner side face of the hole;
forming a first charge storage film on the first film;
forming a second film of an insulator on the first charge storage film;
forming a semiconductor layer on the second film;
removing the sacrificial layers so as to expose the first film;
exposing the first charge storage film by removing the first film in an area where the sacrificial layers are removed;
selectively forming a second charge storage film on the exposed first charge storage film; and
forming a third film of an insulator on the second charge storage film,
wherein the second charge storage film is an oxide film, a nitride film, or an oxynitride film, containing at least one of hafnium (Hf), aluminum (Al), and zirconium (Zr).

10. The method of claim 9, further comprising oxidating the second charge storage film after selectively forming the second charge storage film.

11. The method of claim 10, further comprising:
forming a fourth film of an insulator on the third film and the insulating layers exposed by removing the sacrificial layers; and
forming an electrode layer on the fourth film.

12. The method of claim 9, wherein the first charge storage film is an oxide film, a nitride film, or an oxynitride film, containing at least one of hafnium (Hf), aluminum (Al), and zirconium (Zr).

13. A method of manufacturing a semiconductor device, comprising:
forming a stacked body in which sacrificial layers and insulating layers are alternately stacked in a first direction;
forming a hole passing through the stacked body in the first direction;
selectively forming a first film of an insulator on the insulating layers on an inner side face of the hole;
forming a second film of an insulator on the sacrificial layers and the first film;
forming a first charge storage film on the second film and removing the first charge storage film until the second film in an area corresponding to the first film is exposed;
forming a second charge storage film on the second film and a remaining portion of the first charge storage film;
forming a third film of an insulator on the fourth charge storage film; and
forming a semiconductor layer on the third film,
wherein the first charge storage film is an oxide film, a nitride film, or an oxynitride film, containing at least one of hafnium (Hf), aluminum (Al), and zirconium (Zr).

14. The method of claim 13, wherein the first charge storage film is formed on the second film by repeating film formation and etching of the first charge storage film.

15. The method of claim 14, wherein the etching is atomic layer etching.

16. The method of claim 14, wherein repeating the film formation and etching of the third charge storage film are carried out in-situ.

17. The method of claim 13, wherein selectively forming the first film on the insulating layers includes selectively growing the first film from the insulating layers.

18. The method of claim 13, wherein
selectively forming the first film on the insulating layers includes:
selectively forming a fourth film of an insulator on the sacrificial layers on the inner side face of the hole;
forming a fifth film of an insulator on the insulating layers and the fourth film;
removing the fifth film until the fourth film is exposed;
selectively removing the fourth film; and
forming the first film by oxidating the fifth film.

19. The method of claim 13, further comprising:
removing the sacrificial layers;
forming a sixth film of an insulator on the second film and the insulating layers exposed by removing the sacrificial layers; and
forming an electrode layer on the sixth film.

20. The method of claim 13, wherein the second charge storage film is an oxide film, a nitride film, or an oxynitride film, containing at least one of hafnium (Hf), aluminum (Al), and zirconium (Zr).
